(19) United States
(12) Patent Application Publication
(10) Pub. No.: US 2005/0047615 A1
(43) Pub. Date: Mar. 3, 2005

(54) Audio signal amplifier and audio apparatus having the same

(75) Inventors: Akihiro Kawamura, Takatsuki-shi (JP); Keiichi Fujii, Kusatsu-shi (JP); Junko Hirose, Takatsuki-shi (JP)

Correspondence Address: Kenneth L. Cage, Esq.;McDermott, Will & Emery, 600 Thirteenth Street, N.W., Washington, DC, 20005-3096, US

(73) Assignee: MATSUSHITA ELECTRIC INDUSTRIAL CO., LTD.

(21) Appl. No.: 10/923,003

(22) Filed: Aug. 23, 2004

(30) Foreign Application Priority Data
Aug. 25, 2003 (JP) PAT. 2003-300469

(51) Int. Cl. H04H 5/00; H03F 21/00; H03F 3/38

(52) U.S. Cl. 381/120; 330/10

(57) ABSTRACT

To provide an audio signal amplifier and an audio apparatus having the same that automatically set the output level to an optimum level depending on power supply voltage and so on. The audio signal amplifier of the present invention has an input terminal for receiving an audio signal from outside; a demodulating level control signal input terminal for receiving a demodulating level control signal; a variable-gain amplifying circuit for inputting a gain control signal and the audio signal and amplifying the audio signal at an amplifying factor in response to the gain control signal; a demodulating circuit for receiving the output signal of the variable-gain amplifying circuit and a demodulating signal feedback amount control signal and outputting a demodulating signal obtained by demodulating the output signal of the variable-gain amplifying circuit, the demodulating signal varying in level in response to the demodulating signal feedback amount control signal, as the gain control signal; a control circuit for adjusting demodulating level for outputting the demodulating signal feedback amount control signal generated in response to the demodulating level control signal; and a first output terminal for outputting the output signal of the variable-gain amplifying circuit.

### BACKGROUND OF THE INVENTION

The present invention relates to an audio signal amplifier and an audio apparatus having the same.

In recent years, in the field of portable audio equipments (typically battery-operated apparatus) such as notebook PC (notebook-sized personal computer), DVC (Digital Video Camera), DSC (Digital Still Camera) and PDA (Personal Digital Assistant), power supply voltage of the apparatus is set to be low for the reduction of power consumption and other reasons. Further, a smaller and thinner speaker is employed to achieve downsizing and lower cost of the apparatus. As the speaker becomes smaller and thinner, the capability of the speaker itself lowers and its audible volume gets smaller. As a result, its audible volume is not satisfying for its user and there have been the user's requests to turn the audible volume up. However, since the output dynamic range of circuits including an amplifying circuit for driving speaker is small due to lowered power supply voltage of the apparatus, when the level of output signal of the circuits is increased, the waveform of the output signal is restricted by the power supply voltage to become clipped and distorted, resulting in degradation in sound quality. For this reason, there causes the problem that the output level of the audio signal cannot be increased.

### BRIEF SUMMARY OF THE INVENTION

Therefore, it is possible to take measures to increase the power supply voltage of the audio signal amplifier including the amplifying circuit for driving speaker as much as possible by increasing the voltage of the power source for operating the audio signal amplifier or connecting power source lines of the circuits directly to a battery, not through a power supply voltage regulator (typically, DC-DC converter). This enables to increase the output dynamic range of the circuits in the audio signal amplifier.

Referring to FIG. 5 to FIG. 7, an audio signal amplifier and an audio apparatus of a conventional example will be described. Firstly, referring to FIG. 5, the configuration of the audio signal amplifier and the audio apparatus of the conventional example will be described. FIG. 5 is a block diagram for showing the configuration of the conventional audio apparatus (including the audio signal amplifier) having AGC (Auto Gain Control) function. FIG. 5 shows the audio signal amplifier 500 and a speaker 105. The audio signal amplifier 500 has a first input terminal 111, a variable-gain amplifying circuit 101, a demodulating circuit 502, an amplifying circuit for driving speaker 103 and an output terminal 112. In the scope of this specification and claims, the amplification factor of the amplifying circuit may either be equal to or more than 1 or less than 1 (attenuating circuit).

The conventional audio apparatus (including audio signal amplifier 500) is configured as follows. The first input terminal 111 receives an audio signal from outside. The variable-gain amplifying circuit 101 has a second input terminal 121 for receiving the audio signal and a gain control signal input terminal 122 for receiving a gain control signal and amplifies the audio signal at the amplifying factor according to the gain control signal. The demodulating circuit 502 has a third input terminal 123 for receiving an output signal of the variable-gain amplifying circuit 101 and inputs a demodulating signal obtained by demodulating the output signal of the variable-gain amplifying circuit 101 as a gain control signal to the gain control signal input terminal 122. The amplifying circuit for driving speaker 103 receives the output signal of the variable-gain amplifying circuit 101 and outputs a speaker driving signal. The output terminal 112 outputs the speaker driving signal. The speaker 105 receives the speaker driving signal and outputs sound.

The operation of the audio apparatus thus constituted will be described below. For the input audio signal within the scope of a predetermined level, the level of the output signal of the variable-gain amplifying circuit 101 is controlled by the demodulating signal (gain control signal) output from the demodulating circuit 502 so as to be kept substantially constant (hereinafter referred to as “AGC function works”). FIG. 6 is a view for showing an input/output characteristic 601 of the audio signal amplifier 500 in the case of power supply voltage V_{C1}. In the audio signal amplifier 500, the level of the speaker driving signal output from the amplifying circuit for driving speaker 103 within the scope of the input audio level in which AGC function works is set as a level V_{O1} at which the signal is not clipped to the output dynamic range. In FIG. 6, a horizontal axis indicates an input level V_{IN} of the audio signal input to the first input terminal 111 and a vertical axis indicates an output level V_{OUT} Of the audio signal output from the output terminal 112. The horizontal axis and the vertical axis are represented in logarithm form.

In the input/output characteristic 601, in the case of power supply voltage V_{C1}, the input level of the audio signal amplifier 500 at which AGC function starts to work (level at the first input terminal 111) is V₁, and the output level of the audio signal amplifier 500 at this time (level at the output terminal 112) is V_{O1}.

The gain between the input and output of the audio signal amplifier 500 at the time when AGC function does not work (the level of the input audio signal is very small) is defined as G (=V_{OUT}/V_{IN}).

In the input/output characteristic 601, when the input level V_{IN} ranges from 0 to V_{I1}, V_{OUT}=V_{IN}×G (logV_{OUT}=logV_{IN}+logG) and when the input level V_{IN} is equal to or more than V_{I1}, V_{OUT}=V_{O1}. In this way, when the input level V_{IN} is equal to or more than V_{IN}, the demodulating circuit 102 operates and the variable-gain amplifying circuit 101 is controlled by the output signal from the demodulating circuit 102 so as to kept its output signal constant.

By AGC function, the audio signal amplifier 500 of the conventional example prevents the speaker driving signal output from the amplifying circuit for driving speaker 103 from being clipped by the power supply voltage. The device 500 outputs an audio signal of large level within the limits restricted by the power supply voltage while preventing degradation in sound quality due to sound breaking.

However, the audio signal amplifier of the conventional example has the following problem. When AGC function works, the audio signal amplifier of the conventional example outputs a certain output level V_{O1} set by the power supply voltage V_{C1}. Accordingly, in the case where one audio signal amplifier is connected to various equipments such as notebook PC, DVC, DSC and PDA arbitrarily and operated by the power supply voltage supplied from these equipments, the output level V_{O1} cannot be easily changed depending on the power supply voltage of each equipment. For this reason, in the case where one audio signal amplifier can be connected to a plurality of equipments, each of which having a different power supply voltage from each other, the output level V_{O1} of the audio signal amplifier at the time when AGC function works is set, for example, as the level at which the waveform of the audio signal is not clipped when audio signal amplifier is connected to the equipment having the lowest power supply voltage. In this case, however, there is the problem that the output level V_{O1} of the audio signal amplifier is low also when the audio signal amplifier is connected to the equipment having a high power supply voltage.

To increase the output level of the audio signal amplifier, there is a method in which a power source line of the audio signal amplifier is connected directly to a battery, not though a power supply source regulator and the output voltage of the battery is used as power supply source of the audio signal amplifier as it is. FIG. 7 is a view for showing general voltage characteristic of battery. A horizontal axis indicates operating time of the battery connected to the equipment including the audio signal amplifier (unit: hour H) and a vertical axis indicates voltage of the battery (unit: V). The voltage of the battery is not constant and lowers as time passes.

For that reason, when the output level of the audio signal amplifier at the time when AGC function works is set as V_{O1}, the output signal of the audio signal amplifier is clipped by the power supply voltage after the time T has passed. When the output level V_{O1} is increased to be close to the battery voltage at full charge, the sound volume of the speaker becomes larger, but the output signal of the audio signal amplifier is clipped by power supply voltage sooner. When the output level V_{O1} is decreased, continuous available time of the battery becomes longer. At this time, however, for example, in the case where the battery is in substantially full charge state, the problem occurs that broad output dynamic range that high power supply voltage allows is not used effectively, resulting in small sound volume of the speaker.

Moreover, in various equipments, the optimum output level V_{O1} is not always a level slightly lower than the power supply voltage V_{C1} (for example, the input/output characteristic in FIG. 6) and other level may be preferable. Accordingly, it is desirable that the output level V_{O1} of the audio signal amplifier at the time when AGC function works can be set to the output level according to the characteristic of the equipment. However, in the conventional audio signal amplifier, it is difficult to set the output level V_{O1} of the audio signal amplifier at the time when AGC function works to the output level according to the characteristic of the equipment.

The present invention solves the above-mentioned conventional problem and intends to provide an audio signal amplifier and an audio apparatus having the same that automatically set the output level to an optimum level in response to a control signal.

The present invention intends to provide an audio signal amplifier and an audio apparatus having the same that automatically set the output level to an optimum level according to power supply voltage.

The present invention intends to provide an audio signal amplifier and an audio apparatus having the same that automatically set the output level to an optimum level according to connected equipment.

To solve the above-mentioned problem, the present invention has the following configuration. The audio signal amplifier from one aspect of the present invention has an input terminal for receiving an audio signal from an outside; a demodulating level control signal input terminal for receiving a demodulating level control signal; a variable-gain amplifying circuit for inputting a gain control signal and the above-mentioned audio signal and amplifying the above-mentioned audio signal at an amplifying factor in response to the above-mentioned gain control signal; a demodulating circuit for receiving the output signal of the above-mentioned variable-gain amplifying circuit and a demodulating signal feedback amount control signal and outputting a demodulating signal obtained by demodulating the output signal of the above-mentioned variable-gain amplifying circuit, the above-mentioned demodulating signal varying in level in response to the above-mentioned demodulating signal feedback amount control signal, as the above-mentioned gain control signal; a control circuit for adjusting a demodulating level for outputting the above-mentioned demodulating signal feedback amount control signal generated in response to the above-mentioned demodulating level control signal; and a first output terminal for outputting the output signal of the above-mentioned variable-gain amplifying circuit.

The present invention has the effect of realizing the audio signal amplifier that automatically sets the output level to an optimum level in response to the control signal.

By making power supply voltage the demodulating level control signal, the present invention has the effect of realizing an audio signal amplifier that automatically sets the output level to an optimum level depending on the power supply voltage.

By providing an external connected terminal and controlling the audio output level by the use of a demodulating level control signal that output from an external equipment connected to an audio signal amplifier and input to the external terminal, the present invention has the effect of realizing the audio signal amplifier that automatically sets the audio output level to an optimum level depending on the connected external equipment. The demodulating level control signal may either be analog or digital signal.

In the above-mentioned audio signal amplifier from another aspect of the present invention, the above-mentioned demodulating level control signal input terminal is connected to a power supply line of the audio signal amplifier, the above-mentioned control circuit for adjusting demodulating level outputs the above-mentioned demodulating signal feedback amount control signal in response to the above-mentioned demodulating level control signal as power supply voltage and the above-mentioned demodulating circuit outputs the above-mentioned demodulating signal that becomes to a lower level as the power supply voltage becomes a higher level.

For example, the audio signal amplifier of the present invention is connected directly to a battery, the audio output level of the audio signal amplifier becomes higher if the battery is in a substantially full charge state, and the audio output level of the audio signal amplifier becomes lower if the battery is in a substantially full discharge state. Also in the case where the audio signal amplifier of the present invention is connected to a plurality of equipments, each of which has a different power supply voltage with each other, and is operated by the power supply voltage fed from the equipments, similar effect can be obtained.

In the above-mentioned audio signal amplifier from another aspect of the present invention, the above-mentioned variable-gain amplifying circuit has a gain control signal input terminal for receiving the above-mentioned gain control signal, the above-mentioned demodulating circuit has a demodulator for demodulating the output signal of the above-mentioned variable-gain amplifying circuit, a first path for transmitting an output current of the above-mentioned demodulator to the above-mentioned gain control signal input terminal at a predetermined impedance and a second path for throwing out the output current of the above-mentioned demodulator by bypassing, and the above-mentioned second path has a variable impedance device for changing current passing therethrough in response to the above-mentioned demodulating signal feedback amount control signal. With this configuration, the audio signal amplifier that automatically sets the output level to an optimum level in response to the demodulating level control signal can be realized.

In the above-mentioned audio signal amplifier from another aspect of the present invention, the above-mentioned variable-gain amplifying circuit has a gain control signal input terminal for receiving the above-mentioned gain control signal, the above-mentioned demodulating circuit has a demodulator for demodulating the output signal of the above-mentioned variable-gain amplifying circuit and a first path for transmitting an output current of the above-mentioned demodulator to the above-mentioned gain control signal input terminal at a predetermined impedance, and the above-mentioned first path has a variable impedance device for changing current passing therethrough in response to the above-mentioned demodulating signal feedback amount control signal. With this configuration, the audio signal amplifier that automatically sets the output level to an optimum level in response to the demodulating level control signal can be realized.

The above-mentioned audio signal amplifier from another aspect of the present invention further has an amplifying circuit for driving a speaker for receiving an output signal of the above-mentioned first output terminal and outputting a speaker driving signal and a second output terminal for outputting the above-mentioned speaker driving signal. With this configuration, the audio signal amplifier that automatically sets the sound volume of the speaker to an optimum level in response to the demodulating level control signal can be realized.

The audio apparatus from one aspect of the present invention has the above-mentioned audio signal amplifier and a speaker for receiving the above-mentioned speaker driving signal and outputting sound. With this configuration, the audio apparatus that automatically sets the sound volume of the speaker to an optimum level in response to the demodulating level control signal can be realized.

The present invention can obtain the advantageous effect of realizing the audio signal amplifier and the audio apparatus that automatically set the output level to an optimum level in response to the control signal.

The present invention can obtain the advantageous effect of realizing the audio signal amplifier and the audio apparatus that automatically set the output level to an optimum level depending on the power supply voltage. For example, even when the power supply voltage changes, the output audio signal can be maintained to be the highest level within the scope in which sound output from the speaker is not distorted. Moreover, it is possible to output the audio signal of the level at which the output dynamic range of the circuit set by the power supply voltage is used without waste.

By providing an external connected terminal and controlling the audio output level by the use of a demodulating level control signal that output from an external equipment connected to an audio signal amplifier and input to the external terminal, the present invention has the advantageous effect of realizing the audio signal amplifier and the audio apparatus that automatically set the output audio signal to an optimum level depending on the connected equipment.

The novel features of the invention are set forth with particularity in the appended claims. The invention as to both structure and content, and other objects and features thereof will best be understood from the detailed description when considered in connection with the accompanying drawings.

### BRIEF DESCRIPTION OF DRAWINGS

FIG. 1 is a block diagram for showing the configuration of an audio apparatus in accordance with a first embodiment of the present invention.

FIG. 2 is a view for showing input/output characteristics of an audio signal amplifier in accordance with the first embodiment of the present invention.

FIG. 3 is a view for showing general voltage characteristic of battery and characteristic of an output level of the audio signal amplifier in accordance with the first embodiment of the present invention.

FIG. 4 is a block diagram for showing the configuration of an audio apparatus in accordance with a second embodiment of the present invention.

FIG. 5 is a block diagram for showing the configuration of an audio apparatus of a conventional example.

FIG. 6 is a view for showing an input/output characteristic of an audio signal amplifier of the conventional example.

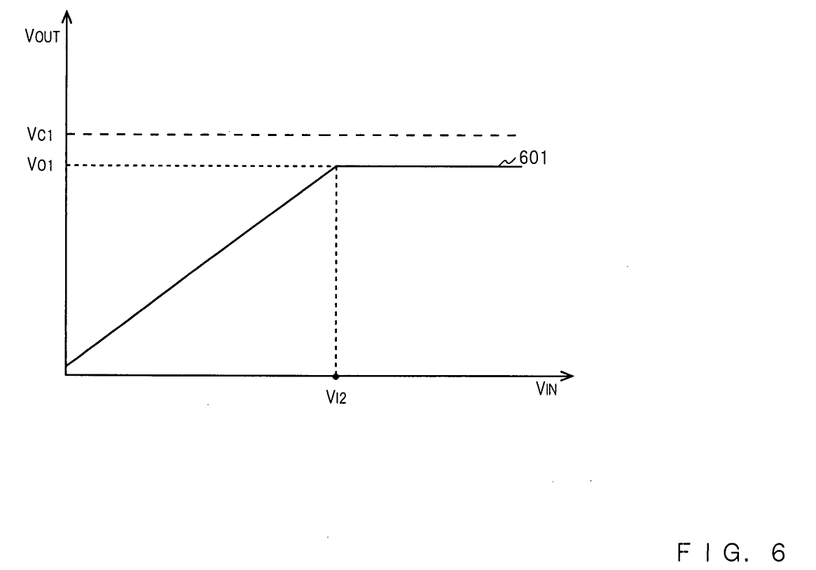

FIG. 7 is a view for showing general power supply voltage characteristic of battery.

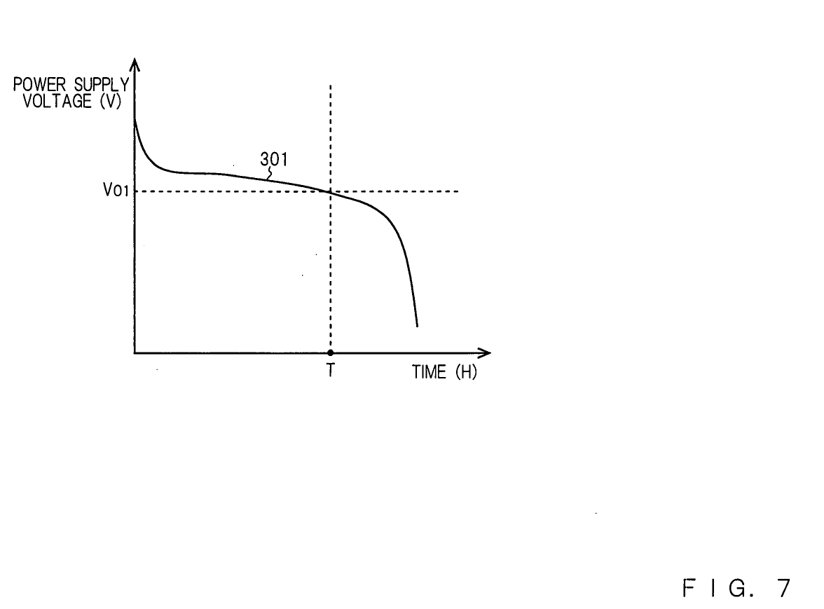

Part or All of the drawings are drawn schematically for diagrammatic representation and it should be considered that they do not necessarily reflect relative size and position of components shown therein.

### DETAILED DESCRIPTION OF THE INVENTION

Embodiments that specifically describe best modes for conducting the present invention will be described referring to figures below.

<<First Embodiment>>

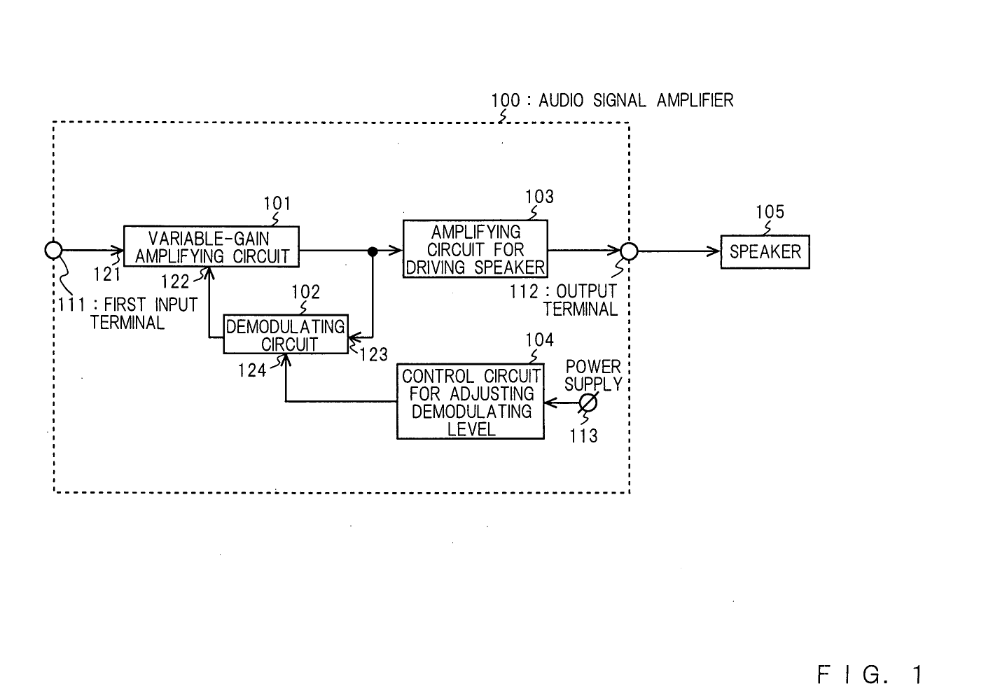

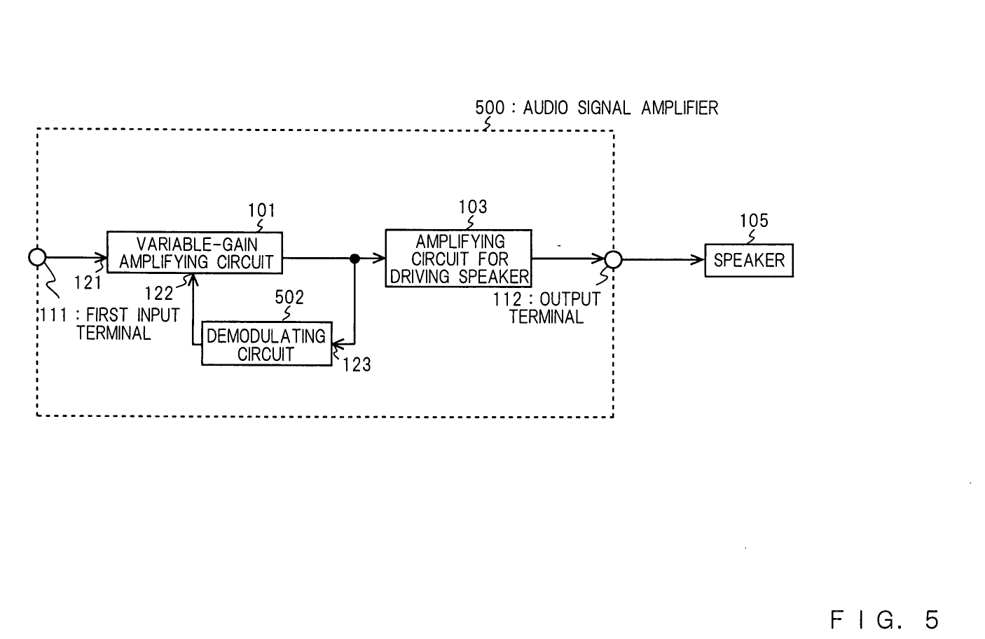

Referring to FIG. 1 to FIG. 3, an audio signal amplifier and an audio apparatus in accordance with a first embodiment of the present invention will be described. Firstly, referring to FIG. 1, the configuration of the audio signal amplifier and the audio apparatus in accordance with the first embodiment of the present invention will be described. FIG. 1 is a block diagram for showing the configuration of the audio apparatus (including the audio signal amplifier) having AGC function in accordance with the first embodiment of the present invention. FIG. 1 shows the audio signal amplifier 100 and a speaker 105. The audio signal amplifier 100 has a first input terminal 111, a variable-gain amplifying circuit 101, a demodulating circuit 102, a control circuit for adjusting demodulating level 104, an amplifying circuit for driving speaker 103 and an output terminal 112. Reference numeral 113 is a power supply input terminal for inputting power supply voltage of the audio signal amplifier 100. Power supply line of the audio signal amplifier 100 or the audio apparatus of the first embodiment is connected directly to an output terminal of a battery (either primary battery or secondary battery is available). In FIG. 1, the same reference numerals are assigned to the same blocks in the conventional example (FIG. 5).

The audio apparatus (including audio signal amplifier 100) in accordance with the first embodiment of the present invention is configured as follows. The first input terminal 111 receives an audio signal from outside. The variable-gain amplifying circuit 101 has a second input terminal 121 for receiving the audio signal and a gain control signal input terminal 122 for receiving a gain control signal and amplifies the audio signal at the amplifying factor according to the gain control signal. The power supply input terminal (the demodulating level control signal input terminal) 113 inputs power supply voltage (demodulating level control signal). The control circuit for adjusting demodulating level 104 outputs a demodulating signal feedback amount control signal generated according to the power supply voltage (demodulating level control signal). The demodulating circuit 102 has a third input terminal 123 for receiving the output signal of the variable-gain amplifying circuit 101 and a demodulating signal feedback amount control signal input terminal 124 for receiving the demodulating signal feedback amount control signal and inputs a demodulating signal obtained by demodulating the output signal of the variable-gain amplifying circuit 101 and varies in response to the demodulating signal feedback amount control signal in level as a gain control signal to the gain control signal input terminal 122. The amplifying circuit for driving the speaker 103 receives the output signal of the variable-gain amplifying circuit 101 and outputs a speaker driving signal. The output terminal 112 outputs the speaker driving signal. The speaker 105 receives the speaker driving signal and outputs sound.

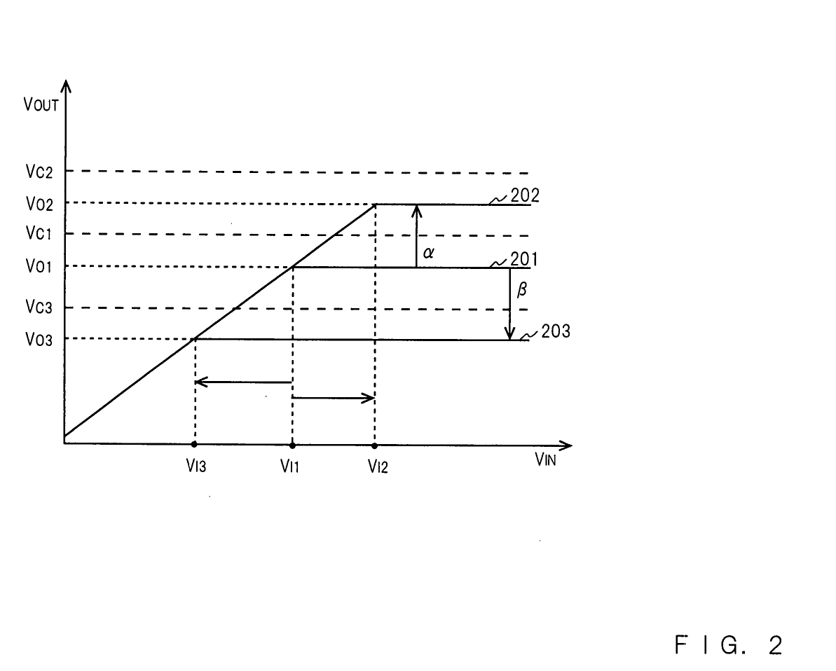

The operation of the audio apparatus thus constituted will be described below. For the input audio signal within the scope of a predetermined level, the level of the output signal of the variable-gain amplifying circuit 101 is controlled by the demodulating signal (gain control signal) output from the demodulating circuit 102 so as to be kept substantially constant. FIG. 2 is a view for showing input/output characteristics 201, 202 and 203 of the audio signal amplifier 100 in the case of power supply voltage (voltage of the power supply input terminal 113) of V_{C1}, V_{C2} (=V_{C1}+α (α is a positive number)) and V_{C3} (=V_{C1}−β (β is a positive number)), respectively. In FIG. 2, a horizontal axis indicates an input level V_{IN} of the audio signal input to the first input terminal 111 and a vertical axis indicates an output level V_{OUT} of the audio signal output from the output terminal 112. The horizontal axis and the vertical axis are represented in logarithm form. The input/output characteristic of the audio signal amplifier 100 varies depending on the power supply voltage. Once the power supply voltage is determined to be a certain value, the input/output characteristic of the audio signal amplifier 100 at the power supply voltage is determined uniquely.

In FIG. 2, in the case where the voltage of the power supply input terminal 113 (power supply voltage) is V_{C1}, the input level of the audio signal amplifier 100 at which AGC function starts to work (level at the first input terminal 111) is V_{I1} and the output level of the audio signal amplifier 100 at this time (level at the output terminal 112) is V_{O1}. The gain between the input and output of the audio signal amplifier 100 at the time when AGC function does not work (the level of the input audio signal is very small) is defined as G (=V_{OUT}/V_{IN}). For the input/output characteristic 201, when the input level V_{IN} ranges from 0 to V_{I1}, V_{OUT}=V_{IN}×G (logV_{OUT}=logV_{IN}+logG) and when the input level V_{IN} is equal to or more than V_{I1}, V_{OUT}=V_{O1}. In this way, when the input level V_{IN} is equal to or more than V_{I1}, the demodulating circuit 102 operates and the variable-gain amplifying circuit 101 is controlled by the output signal from the demodulating circuit 102 so as to kept its output signal constant. The output level V_{O1} is slightly lower than the power supply voltage V_{C1} and the waveform of the output signal of the audio signal amplifier 100 is not distorted (the output level V_{O1} is set to the level at which the waveform is not clipped by the power supply voltage).

In the case where the voltage of the power supply input terminal 113 (power supply voltage) is V_{C2}, the input level of the audio signal amplifier 100 at which AGC function starts to work is V_{I2} and the output level of the audio signal amplifier 100 at this time is V_{O2}. For the input/output characteristic 202, when the input level V_{IN} ranges from 0 to V_{I2}, V_{OUT}=V_{IN}×G (logV_{OUT}=logV_{IN}+logG) and when the input level V_{IN} is equal to or more than V_{I2}, V_{OUT}=V_{O2}. When the input level V_{IN} is equal to or more than V_{I2}, AGC function works, thereby to lead to V_{OUT}=V_{O2}. The output level V_{O2} is slightly lower than the power supply voltage V_{C2} and the waveform of the output signal of the audio signal amplifier 100 is not distorted (the output level V_{O2} is set to the level at which the waveform is not clipped by the power supply voltage).

In the case where the voltage of the power supply input terminal 113 (power supply voltage) is V_{C3}, the input level of the audio signal amplifier 100 at which AGC function starts to work is V_{I3} and the output level of the audio signal amplifier 100 at this time is V_{O3}. For the input/output characteristic 203, when the input level V_{IN} ranges from 0 to V_{I3}, V_{OUT}=V_{IN}×G (logV_{OUT}=logV_{IN}+logG) and when the input level V_{IN} is equal to or more than V_{I3}, V_{OUT}=V_{O3}. When the input level V_{IN} is equal to or more than V_{I3}, AGC function works, thereby to lead to V_{OUT}=V_{O3}. The output level V_{O3} is slightly lower than the power supply voltage V_{C3} and the waveform of the output signal of the audio signal amplifier 100 is not distorted (the output level V_{O3} is set to the level at which the waveform is not clipped by the power supply voltage).

When the voltage of the power supply input terminal 113 (power supply voltage) becomes higher than V_{C1} by α (α is a positive number) (the voltage of the power supply input terminal 113 (power supply voltage) becomes V_{C2} (=V_{C1}+α)), the control circuit for adjusting demodulating level 104 changes the demodulating signal feedback amount control signal depending on the voltage of the power supply input terminal 113 (power supply voltage). This increases the input level of the variable-gain amplifying circuit 101 and the demodulating circuit 102 at which AGC function starts to work, and in turn increases the output level within the scope of the input level at which AGC function works. Specifically, the input level at which the variable-gain amplifying circuit operates becomes the level V_{I2} higher than V_{I1}. When the power supply voltage changes from V_{C1} to V_{C2}, the output level changes from V_{O1} to V_{O2} (=V_{O1}+α) while keeping the state of not being clipped with respect to the output dynamic range of the amplifying circuit for driving 103. In the conventional example, the output level is fixed at V_{O1} and therefore the level difference a is not used effectively.

When the voltage of the power supply input terminal 113 (power supply voltage) becomes lower than V_{C1} by β (β is a positive number) (power supply voltage becomes V_{C3} (=V_{C1}−β)), the control circuit for adjusting demodulating level 104 changes the demodulating signal feedback amount control signal depending on the power supply voltage in the reverse direction to the above-mentioned case. This decreases the input level of the variable-gain amplifying circuit 101 and the demodulating circuit 102 at which AGC function starts to work, and in turn decreases the output level within the scope of the input level at which AGC function works. Specifically, the input level at which the variable-gain amplifying circuit operates becomes the level V_{I3} lower than V_{I1}. When the power supply voltage changes from V_{C1} to V_{C3}, the output level changes from V_{O1} to V_{O3} (=V_{O1}−β) while keeping the state of not being clipped with respect to the output dynamic range of the amplifying circuit for driving the speaker 103. In the conventional example, the output level is fixed at V_{O1} and therefore output level is clipped, resulting in degradation in sound quality.

In the first embodiment of the present invention, as the output level at which AGC function works changes with change in the power supply voltage, the optimum output level can be maintained at all times. As a result, even when the power supply voltage changes, it is possible to output the audio signal of the output level at which waveform is not distorted and the power supply voltage is used effectively.

The demodulating circuit 102 and the control circuit for adjusting demodulating level 104 have an arbitrary configuration. For example, they have the following configuration. The demodulating circuit 102 has a demodulator for demodulating the output signal of the variable-gain amplifying circuit 101, a first path for transmitting an output current of the demodulator to the gain control signal input terminal 122 at a predetermined impedance and a second path for throwing out the output current of the demodulator by bypassing. The second path has a variable impedance device for changing current passing therethrough in response to the demodulating signal feedback amount control signal. The control circuit for adjusting demodulating level 104 has a first transistor for passing a current depending on the power supply voltage. The higher the power supply voltage, the higher the current driving capacity of the first transistor (the impedance of the first transistor is low). At the second path of the demodulating circuit 102 is provided a second transistor (variable impedance device) that forms a mirror circuit along with the first transistor. The second transistor bypasses the output current of the demodulator depending on the power supply voltage. In this way, the demodulating circuit 102 and the control circuit for adjusting demodulating level 104 carry out the above-mentioned function.

The demodulating circuit 102 and the control circuit for adjusting demodulating level 104 may have the following configuration. The demodulating circuit 102 has a demodulator for demodulating the output signal of the variable-gain amplifying circuit 101 and a first path for transmitting an output current of the demodulator to the gain control signal input terminal 122 at a predetermined impedance. The first path has a variable impedance device (such as a FET (Field Effect Transistor)) for changing current passing therethrough in response to the demodulating signal feedback amount control signal. The control circuit for adjusting demodulating level 104 generates the control voltage of the FET depending on the power supply voltage. The higher the power supply voltage, the lower the current driving capacity of a third transistor (the impedance of the third transistor is high). In this way, the demodulating circuit 102 and the control circuit for adjusting demodulating level 104 carry out the above-mentioned function.

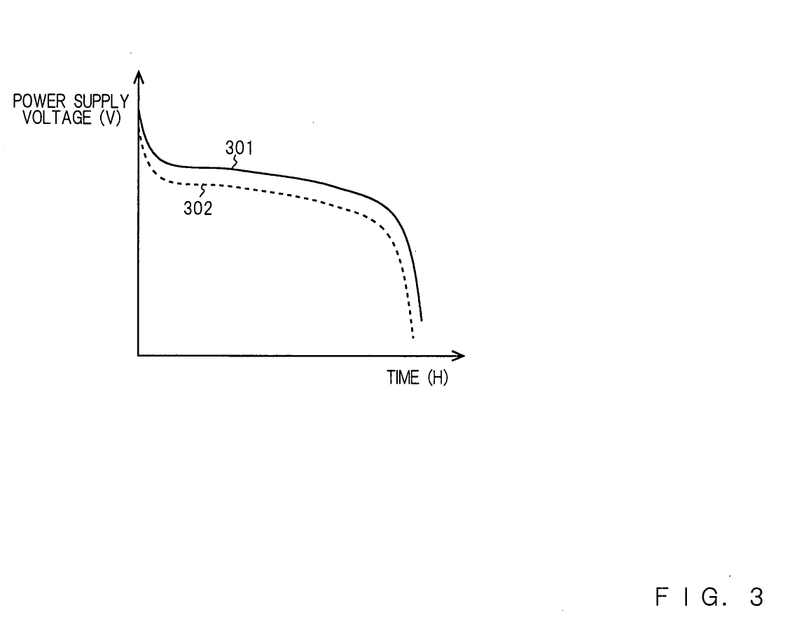

FIG. 3 is a view for showing the general voltage characteristic of battery and the characteristic of the output level of the audio signal amplifier 100 in accordance with the first embodiment of the present invention at the time when AGC function works. In FIG. 3, a horizontal axis indicates operating time of the battery connected to the equipment including the audio signal amplifier 100 (unit: hour H) and a vertical axis indicates voltage of the battery (unit: V). 301 shows the general time-voltage characteristic of battery. 302 shows the characteristic of the output level of the audio signal amplifier 100 in the case of the battery voltage characteristic 301. The output level is set so as not to be clipped with respect to the output dynamic range of the amplifying circuit for driving speaker 103. With the configuration of this embodiment, even when power is fed from the battery in which voltage varies vastly, the output level can be controlled optimally depending on the power supply voltage at that time.

<<Second Embodiment>>

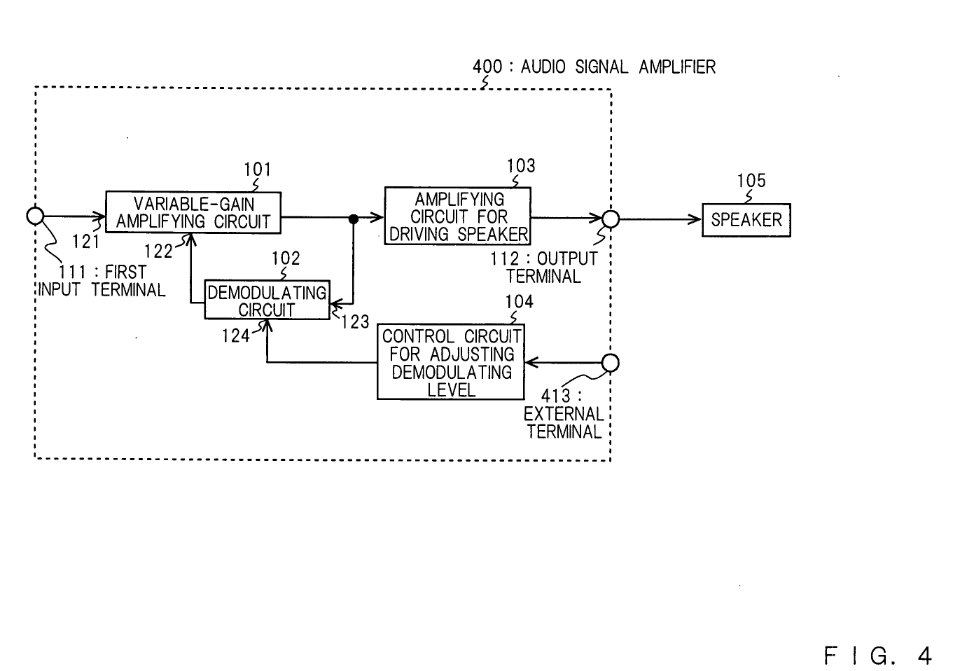

Referring to FIG. 4, an audio signal amplifier and an audio apparatus in accordance with a second embodiment of the present invention will be described. Firstly, referring to FIG. 4, the configuration of the audio signal amplifier and the audio apparatus in accordance with the second embodiment of the present invention will be described. FIG. 4 is a block diagram for showing the configuration of the audio apparatus (including the audio signal amplifier) having AGC function in accordance with the second embodiment of the present invention. The audio apparatus of the second embodiment has an external terminal 413 connected to the control circuit for adjusting demodulating level 104 in place of the power supply input terminal 113 of the first embodiment (FIG. 1). The audio apparatus of the second embodiment is identical to that of the first embodiment in other components. In FIG. 4, the same reference numerals are assigned to the same blocks as in the first embodiment (FIG. 1) and description of the same blocks will be omitted.

The audio apparatus has a first input terminal 111 and the external terminal 413 on a connecting panel to external equipment. The external equipment inputs an audio signal to the first input terminal 111 and inputs a demodulating level control signal as an analog or digital signal to the external terminal 413. Alternatively, it may be configured so that the external equipment does not input the audio signal to the first input terminal 111 and inputs the demodulating level control signal to the external terminal 413.

The audio apparatus changes the output level at the time when AGC function works in response to the demodulating level control signal input from the external terminal 413. Details of this function have been described in detail in the first embodiment.

With the configuration in accordance with the second embodiment of the present invention, the audio apparatus changes the output level at the time when AGC function works in accordance with the specification of various equipment. This enables, for example, to output the audio signal of the output level at which the waveform is not distorted and the power supply voltage is used effectively, or the audio signal of large output level at which the waveform is slightly distorted, depending on the external equipment. The external equipment can output sound through the audio apparatus in accordance with the specification of the external equipment.

In the second embodiment, the power supply line of the audio apparatus is connected directly to the battery. Alternatively, the power supply line of the audio apparatus may be connected to, for example, the output terminal of the power supply voltage regulator in which the output voltage varies to some extent.

The audio signal amplifier and audio apparatus of the present invention are useful as a battery-operated portable audio equipment.

While preferred embodiments of the present invention have been described in detail to a certain degree, it is to be understood that, within the scope and spirit of the claims made herein, the invention may be practiced otherwise than as specifically described herein, the invention may be modified in arrangement and detail without departing from such scope and spirit.

1. An audio signal amplifier comprising:
an input terminal for receiving an audio signal from an outside;
a demodulating level control signal input terminal for receiving a demodulating level control signal;
a variable-gain amplifying circuit for inputting a gain control signal and said audio signal and amplifying said audio signal at an amplifying factor according to said gain control signal;
a demodulating circuit for receiving the output signal of said variable-gain amplifying circuit and a demodulating signal feedback amount control signal and outputting a demodulating signal obtained by demodulating the output signal of said variable-gain amplifying circuit, said demodulating signal varying in level in response to said demodulating signal feedback amount control signal, as said gain control signal;
a control circuit for adjusting a demodulating level for outputting said demodulating signal feedback amount control signal generated in response to said demodulating level control signal; and
a first output terminal for outputting the output signal of said variable-gain amplifying circuit.

2. An audio signal amplifier as stated in claim 1, wherein
said demodulating level control signal input terminal is connected to a power supply line of the audio signal amplifier,
said control circuit for adjusting demodulating level outputs said demodulating signal feedback amount control signal in response to said demodulating level control signal as power supply voltage and
said demodulating circuit outputs said demodulating signal that becomes to a lower level as the power supply voltage becomes a higher level.

3. An audio signal amplifier as stated in either claim 1 or 2, wherein
said variable-gain amplifying circuit has a gain control signal input terminal for receiving said gain control signal,
said demodulating circuit has a demodulator for demodulating the output signal of said variable-gain amplifying circuit, a first path for transmitting an output current of said demodulator to said gain control signal input terminal at a predetermined impedance and a second path for throwing out the output current of said demodulator by bypassing, and
said second path has a variable impedance device for changing current passing therethrough in response to said demodulating signal feedback amount control signal.

4. An audio signal amplifier as stated in either claim 1 or 2, wherein
said variable-gain amplifying circuit has a gain control signal input terminal for receiving said gain control signal,
said demodulating circuit has a demodulator for demodulating the output signal of said variable-gain amplifying circuit and a first path for transmitting an output current of said demodulator to said gain control signal input terminal at a predetermined impedance, and
said first path has a variable impedance device for changing current passing therethrough in response to said demodulating signal feedback amount control signal.

5. An audio signal amplifier as stated in claim 1, further comprising an amplifying circuit for driving a speaker for receiving an output signal of said first output terminal and outputting a speaker driving signal and a second output terminal for outputting said speaker driving signal.

6. An audio apparatus comprising the audio signal amplifier as stated in claim 5 and a speaker for receiving said speaker driving signal and outputting sound.
